(19) United States
(12) Patent Application Publication
(10) Pub. No.: US 2016/0093511 A1
(43) Pub. Date: Mar. 31, 2016

(54) MULTIGATE TRANSISTOR DEVICE AND METHOD OF ISOLATING ADJACENT TRANSISTORS IN MULTIGATE TRANSISTOR DEVICE USING SELF-ALIGNED DIFFUSION BREAK (SADB)

(71) Applicant: QUALCOMM Incorporated, San Diego, CA (US)

(72) Inventors: Samit SENGUPTA, San Diego, CA (US); Shashank EKBOTE, San Diego, CA (US); Da YANG, San Diego, CA (US); Choh Fei YEAP, San Diego, CA (US)

(21) Appl. No.: 14/496,365

(22) Filed: Sep. 25, 2014

(51) Int. Cl. H01L 21/3213; H01L 21/762; H01L 27/088

(52) U.S. Cl. CPC H01L 21/32139; H01L 27/0886; H01L 21/76224

(57) ABSTRACT

A multigate transistor device such as a fin-shaped field effect transistor (FinFET) is fabricated by applying a self-aligned diffusion break (SADB) mask having an opening positioned to expose an area of at least one portion of at least one gate stripe designated as at least one tie-off gate in the multigate transistor device and removing the tie-off gate through the opening of the SADB mask to isolate transistors adjacent to the tie-off gate.

### FIELD OF DISCLOSURE

Various embodiments described herein relate to fabrication of semiconductor devices, and more particularly, to fabrication of multigate transistor devices such as fin-shaped field effector transistor (FinFET) devices.

### BACKGROUND

Multigate transistors have been implemented in integrated circuit chips for area efficiency. Examples of multigate transistors include fin-shaped field effect transistors (FinFETs) having multiple fins disposed on two sides of a gate stripe, with fins on one side of the gate stripe serving as sources and fins on the other side of the gate stripe serving as drains of the FinFETs. Examples of typical FinFET devices include devices in which transistor arrays are formed by multiple gate stripes in parallel with one another, which are positioned perpendicular to multiple oxide diffusion (OD) stripes in parallel with one another. The OD stripes are positioned like fins on two sides of each gate stripe. Each pair of source and drain and a portion of the gate stripe between such pair of source and drain may be implemented as an individual transistor. Adjacent transistors may need to be isolated in order for a pair of source and drain and the associated portion of the gate stripe to serve as an individual transistor.

Various conventional techniques have been devised for isolating adjacent transistors in FinFET layouts, including, for example, techniques using a single OD break, a double OD break, or continuous OD. With either a single or double OD break, a break in an OD stripe is created during the OD masking step. A double OD break is a larger break than a single OD break for better isolation but sacrifices a column (or row) of gates in comparison to a single OD break. Alignment of OD breaks may be difficult with either single or double OD break in practice. In continuous OD, no OD break is created, but a gate that is selected for “tie-off” to isolate two adjacent transistors is driven to a low voltage or turned off to mitigate leakage across the adjacent transistors. In practice, some leakage may still exist with continuous OD because there is no physical break between the transistors.

### SUMMARY

Exemplary embodiments are directed to an integrated circuit device, such as a device comprising multigate transistors or fin-shaped field effect transistors (FinFETs), and a method of fabricating the same, using a self-aligned diffusion break (SADB) mask.

In an embodiment, a method of making an integrated circuit is provided, the method comprising: applying a self-aligned diffusion break (SADB) mask to a multigate transistor device comprising a plurality of transistors, the SADB mask having an opening positioned to expose an area over at least one portion of at least one gate stripe designated as at least one tie-off gate, said at least one gate stripe disposed across at least one oxide diffusion (OD) stripe of the multigate transistor device; and removing said at least one tie-off gate through the opening of the SADB mask to isolate transistors adjacent to said at least one tie-off gate.

In another embodiment, a method for making an integrated circuit is provided, the method comprising the steps for: applying a self-aligned diffusion break (SADB) mask to a multigate transistor device comprising a plurality of transistors, the SADB mask having an opening positioned to expose an area over at least one portion of at least one gate stripe designated as at least one tie-off gate, said at least one gate stripe disposed across at least one oxide diffusion (OD) stripe of the multigate transistor device; and removing said at least one tie-off gate through the opening of the SADB mask to isolate transistors adjacent to said at least one tie-off gate.

In another embodiment, an integrated circuit device is provided, the device comprising: a plurality of gate stripes; a plurality of oxide diffusion (OD) stripes disposed across the gate stripes, wherein at least one portion of at least one of the gate stripes and at least one portion of at least one of the OD stripes are removed to form at least one void; and an insulating dielectric in said at least one void to isolate transistors adjacent to said at least one void.

In yet another embodiment, a multigate transistor device is provided, the device comprising: a plurality of gate stripes; a plurality of oxide diffusion (OD) stripes disposed across the gate stripes, wherein at least one portion of at least one of the gate stripes and at least one portion of at least one of the OD stripes are removed to form at least one void; and an insulating dielectric deposited in said at least one void to isolate transistors adjacent to said at least one void.

### BRIEF DESCRIPTION OF THE DRAWINGS

The accompanying drawings are presented to aid in the description of embodiments and are provided solely for illustration of the embodiments and not limitations thereof.

FIG. 1 is a simplified perspective view of an embodiment of a portion of a fin-shaped field effect transistor (FinFET) device.

FIG. 2 is a simplified top plan view of an embodiment of a portion of a FinFET device with a plurality of gate stripes and a plurality of oxide diffusion (OD) stripes before any portions of the gate stripes and any portions of OD stripes are removed to isolate adjacent transistors in the FinFET device.

FIG. 3 is a simplified top plan view of the portion of the FinFET device of FIG. 2, with a self-aligned diffusion break (SADB) mask having an opening aligned for the removal of three tie-off gates.

FIG. 4 is a sectional view of the FinFET device taken along sectional lines 300a-300b in the top plan view of FIG. 3, showing the SADB mask with an opening over one of the tie-off gates.

FIG. 5 is a sectional view of the FinFET device of FIG. 4 after the removal of the gate region of a tie-off gate.

FIG. 6 is a sectional view of the FinFET device of FIG. 5 showing a void after the removal of a portion of the OD stripe underneath the tie-off gate.

FIG. 7 is a sectional view of the FinFET device of FIG. 6 after the void created by the removal of the OD stripe underneath the tie-off gate is filled with an insulating dielectric.

FIG. 8 is flowchart illustrating an embodiment of a method for fabricating an integrated circuit device.

### DETAILED DESCRIPTION

Aspects of the disclosure are described in the following description and related drawings directed to specific embodiments. Alternate embodiments may be devised without departing from the scope of the disclosure. Additionally, well known elements will not be described in detail or will be omitted so as not to obscure the relevant details of the disclosure.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

The terminology used herein is for the purpose of describing particular embodiments only and is not intended to be limiting of the embodiments. As used herein, the singular forms “a,” “an,” and “the,” are intended to include the plural forms as well, unless the context clearly indicates otherwise. It will be further understood that the terms “comprises,” “comprising,” “includes,” or “including,” when used herein, specify the presence of stated features, integers, steps, operations, elements, or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise.

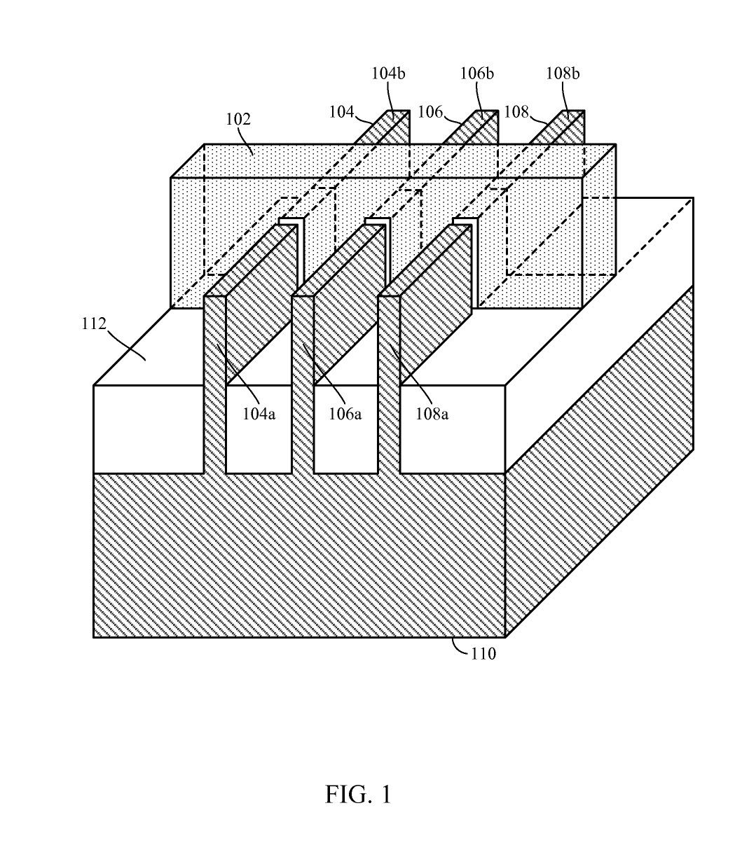

FIG. 1 is a perspective view of an embodiment of a portion of a fin-shaped field effect transistor (FinFET) device to which an embodiment of a method for isolating adjacent transistors using a self-aligned diffusion mask (SADB) for tie-off gate and diffusion etching is applicable. Although embodiments of the method are described with respect to fin-shaped field effect transistor (FinFET) devices, the method is also applicable to semiconductor devices of other layouts, for example, other types of multigate transistor devices, including devices with planar field effect transistor (FET) layouts, without departing from the scope of the disclosure. In the perspective view shown in FIG. 1, the FinFET comprises an elongate gate stripe 102 and a plurality of oxide diffusion (OD) stripes 104, 106 and 108 disposed across the gate stripe 102.

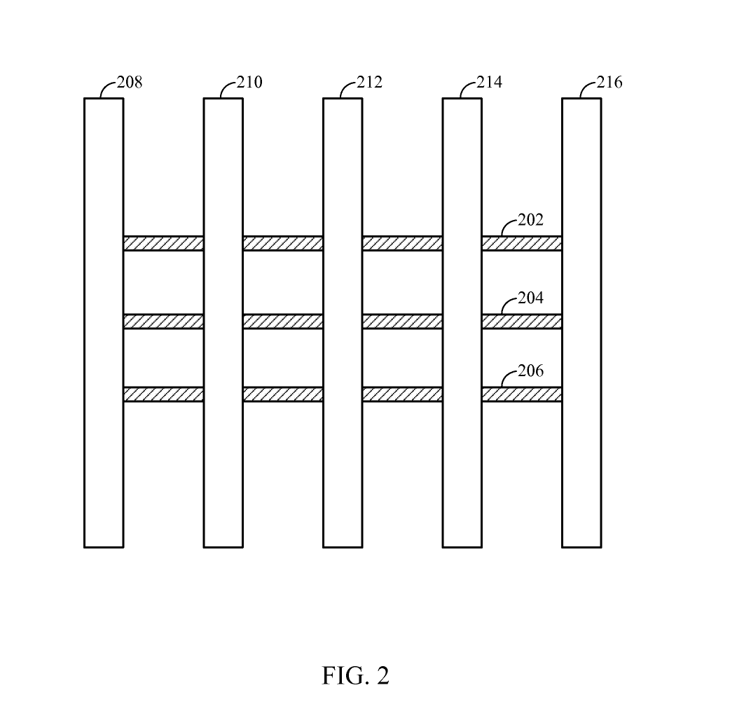

In an embodiment, the OD stripes 104, 106 and 108 extend from both sides of the gate 102 to serve as sources and drains of a multigate transistor device. For example, the OD stripes 104, 106 and 108 may comprise segments 104a, 106a and 108a on one side of the gate 102, serving as sources of the multigate transistor device, and segments 104b, 106b and 108b on the other side of the gate 102, serving as drains of the multigate transistor device, respectively. Thus, the OD stripes 104, 106 and 108 are arranged in the form of “fins” on both sides of the gate 102. In the FinFET device shown in FIG. 1, the top of the gate stripe 102 is above the top of the OD stripes 104, 106 and 108. Although the OD stripes 104, 106 and 108 are shown as being substantially parallel to one another and substantially perpendicular to the gate stripe 102, the OD stripes 104, 106 and 108 need not be strictly in parallel with one another, and they need not be strictly perpendicular to the gate stripe 102. Moreover, although the perspective view of FIG. 1 shows only one gate stripe 102 for simplicity of illustration, multiple gate stripes may be implemented in an integrated circuit device, such as the one shown in the simplified top plan view of FIG. 2 described below. Furthermore, in the embodiment shown in FIG. 1, the FinFET device also comprises a substrate 110, which may comprise a silicon substrate, and an oxide layer 112, which may be fabricated in conventional manners known to persons skilled in the art. Other layers of materials or dopants may also be provided in the FinFET in conventional manners known to persons skilled in the art.

FIG. 2 is a simplified top plan view of an embodiment of a portion of a FinFET device with a plurality of gate stripes and a plurality of oxide diffusion (OD) stripes before any portions of the gate stripes and any portions of OD stripes are removed to isolate adjacent transistors of the FinFET device. In FIG. 2, three OD stripes 202, 204 and 206 are positioned across five gate stripes 208, 210, 212, 214 and 216. In the top plan view of the FinFET device as shown in FIG. 2, the gate stripes 208, 210, 212, 214 and 216 cross over and above the OD stripes 202, 204 and 206. Although the OD stripes 202, 204 and 206 are shown as being parallel to one another, the gate stripes 208, 210, 212, 214 and 216 are shown as being parallel to one another, and the OD stripes 202, 204 and 206 are shown as being perpendicular to the gate stripes 208, 210, 212, 214 and 216 in a grid configuration in FIG. 2, the gate stripes need not be strictly in parallel with one another, the OD stripes need not be strictly in parallel with one another, and the gate stripes need not be strictly perpendicular to the OD stripes in other embodiments.

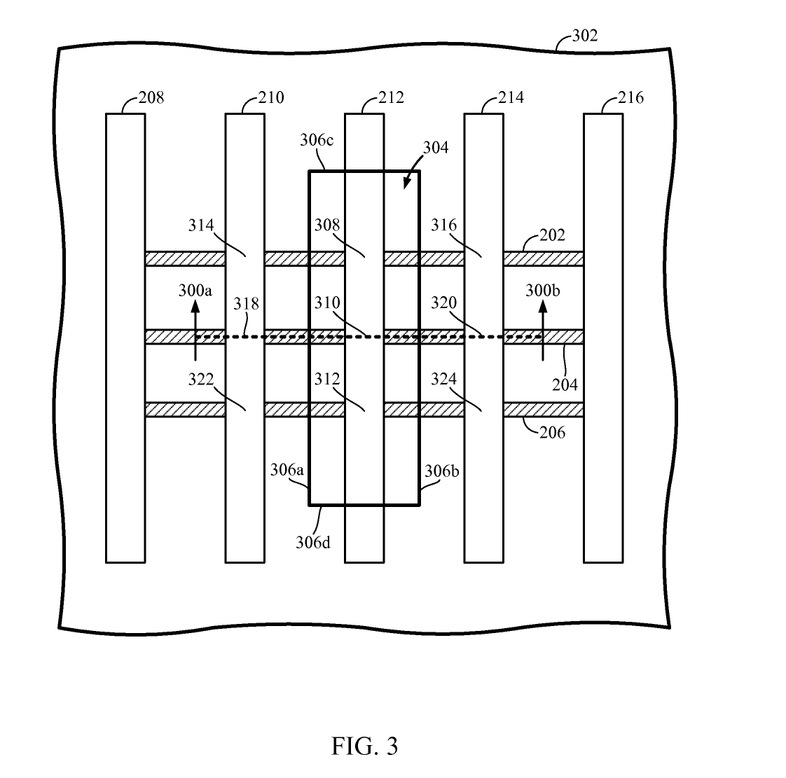

FIG. 3 is a simplified top plan view of the portion of the FinFET device of FIG. 2, with a self-aligned diffusion break (SADB) mask 302 covering at least the portion of the FinFET device as shown in FIG. 2. In an embodiment, the SADB mask 302 has an opening 304 defined by edges 306a, 306b, 306c and 306d. In the embodiment shown in FIG. 3, the opening 304 of the SADB mask 302 is aligned for the removal of three tie-off gates 308, 310 and 312 formed by crossovers of the gate stripe 212 with the OD stripes 202, 204 and 206, respectively. In an embodiment, a tie-off gate is selected for removal in order to isolate two adjacent transistors in an array of transistors in a multigate transistor device. For example, in FIG. 3, the tie-off gate 308 is designated for removal to isolate two adjacent transistors 314 and 316, which are formed by crossovers of the OD stripe 202 with the gate stripes 210 and 214, respectively. In a similar manner, the tie-off gate 310 is designated for removal to isolate two adjacent transistors 318 and 320, which are formed by crossovers of the OD stripe 204 with the gate stripes 210 and 214, respectively, whereas the tie-off gate 312 is designated for removal to isolate two adjacent transistors 322 and 324, which are formed by crossovers of the OD stripe 206 with the gate stripes 210 and 214, respectively. In an embodiment, before the tie-off gates 308, 310 and 312 are removed, the OD stripes 202, 204 and 206 are continuous OD stripes.

In an embodiment, one or more edges of an opening of the SADB mask may be self-aligned to the exposed polysilicon gate regions of tie-off gates designated for removal. For example, in the embodiment shown in FIG. 3, the opening 304 of the SADB mask 302 has a substantially rectangular shape with edges 306a, 306b, 306c and 306d, among which the long edges 306a and 306b are aligned substantially equidistantly to two sides of the gate stripe 212. The short edges 306c and 306d of the opening 304 of the SADB mask 302 may be determined by the number of tie-off gates to be exposed by the mask opening 304 and the distances between OD stripes 202, 204 and 206. Although the opening 304 of the SADB the mask 302 is shown in FIG. 3 to expose three tie-off gates 308, 310 and 312, the mask opening may be planned to remove any number of tie-off gates selected for removal to isolate adjacent transistors that are intended to function as active circuit elements. Moreover, in other embodiments, the mask opening 304 need not be substantially rectangular in shape as shown in FIG. 3. Furthermore, for a large-scale integrated circuit device with a large array of transistors arranged in multiple columns and rows, the SADB mask 302 may have multiple openings over tie-off gates selected for removal anywhere in the transistor array. In an embodiment, the layout of openings in an SADB mask may be planned simply by using markers on the mask.

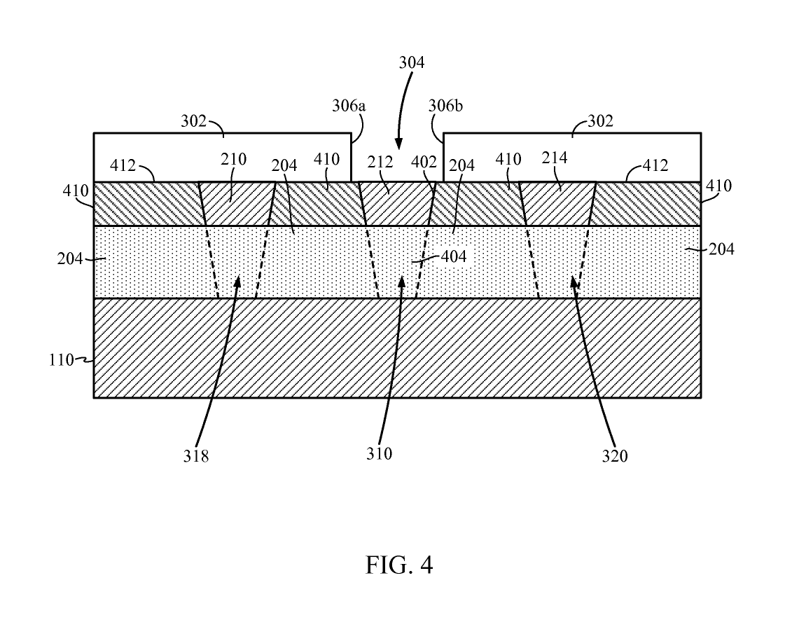

FIG. 4 is a is a sectional view of the FinFET device taken along sectional lines 300a-300b in the top plan view of FIG. 3, showing the SADB mask 302 having an opening 304 defined by edges 306a and 306b over one of the tie-off gates 310, which is formed by the crossover of the gate stripe 212 with the OD stripe 204. Before any part of the FinFET device is removed or etched away through the opening 304 of the SADB mask 302, the tie-off gate 310 may be no different from the gates of other transistors, for example, adjacent transistors 318 and 320 formed by crossovers of the gate stripes 210 and 214 with the OD stripe 204, respectively. In an embodiment, an oxide layer 410 may be disposed on the OD stripe 204 and around the gate stripes 210, 212 and 214 such that the top surface 412 of the oxide layer 410 is flush with the top of the gate stripes 210, 212 and 214 to allow placement of the SADB mask 302 over the gate stripes. In an embodiment, the OD stripe 204 is disposed on a substrate 110, such as a silicon substrate, for example. Other materials or dopants may also be provided in conventional manners known to persons skilled in the art.

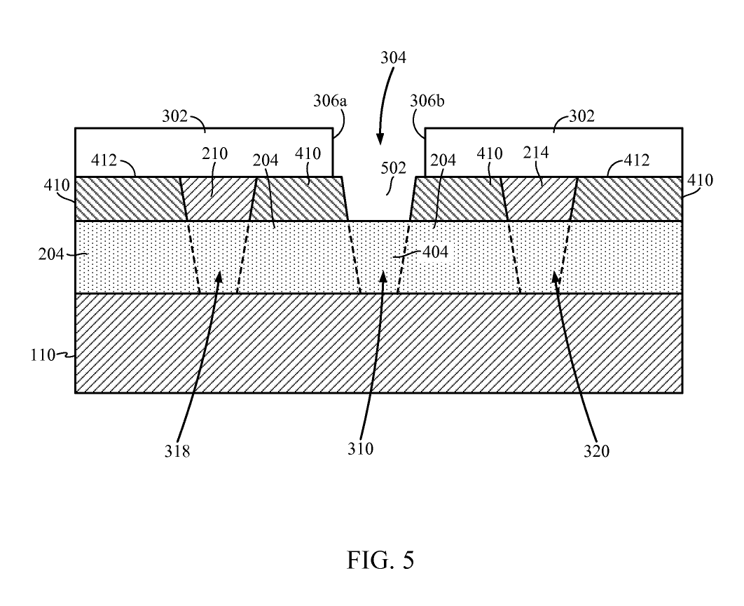

FIG. 5 is a sectional view of the FinFET device of FIG. 4 after removing a portion of the gate material in the gate stripe 212 directly underneath the opening 304 of the SADB mask 302, that is, the gate region of the tie-off gate 310 as shown in FIG. 4. After the removal of the portion of the gate material in the gate stripe 212 which was previously the gate region of the tie-off gate 310, a void 502 is formed directly underneath the opening 304 of the SADB mask 302, as shown in FIG. 5. In an embodiment, the gate region of the tie-off gate 310 is removed by etching through the opening 304 of the SADB mask 302. In an embodiment, etching may be performed by using a conventional etching technique known to persons skilled in the art. For example, in embodiments in which the material of the gate stripe 212 comprises polysilicon, the polysilicon gate material underneath the opening 304 of the SADB mask 302 may be removed by a conventional etching process. In the embodiment shown in FIG. 5, the gate region of the tie-off gate 310 is etched to a depth such that the portion of the OD stripe 204 underneath what was previously the gate region of the tie-off gate 310 is exposed through the void 502 and the opening 304 of the SADB mask 302.

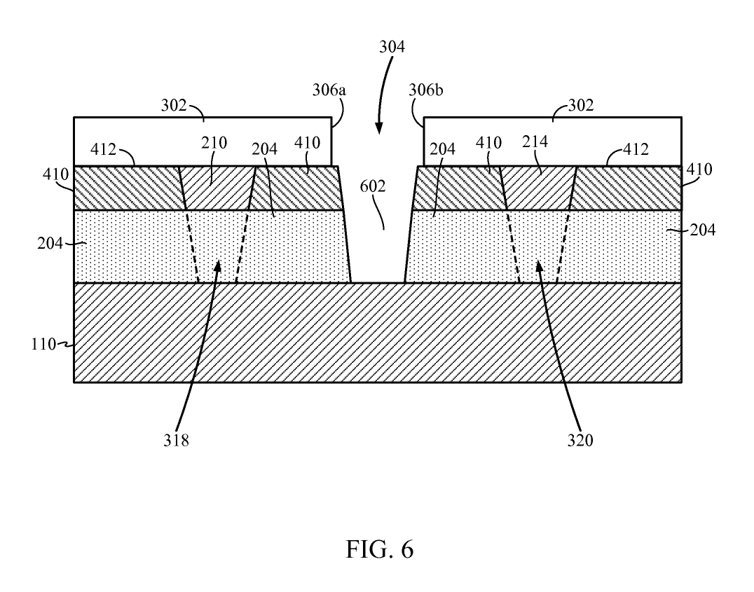

FIG. 6 is a sectional view of the FinFET device of FIG. 5 after further removing the portion of the OD stripe 204 underneath what was previously the gate region of the tie-off gate 310, directly underneath the opening 304 of the SADB mask 302 as previously shown in FIG. 4. After the removal of the portion of the OD stripe 204 underneath what was previously the gate region of the tie-off gate 310, a deeper void 602 is formed under the opening 304 of the SADB mask 302, as shown in FIG. 6. In an embodiment, the portion of the OD stripe 204 underneath the tie-off gate 310 may be removed by using a conventional etching process for removing an OD material known to persons skilled in the art, after the polysilicon gate region 402 of the tie-off gate 310 is removed in an earlier etching process. In another embodiment, the gate region of the tie-off gate and the portion of the OD stripe underneath the gate region of the tie-off gate may be removed in a single step without departing from the scope of the disclosure.

In the embodiment of the top plan view shown in FIG. 3, the opening 304 of the SADB mask 302 is of a substantially rectangular elongate shape over three tie-off gates 308, 310 and 312 formed by crossovers of the gate stripe 212 with three OD stripes 202, 204 and 206, respectively. In such an embodiment, the void 602 as shown in the sectional view of FIG. 6 after the exposed gate regions of the tie-off gates 308, 310 and 312 along the gate stripe 212 as well as portions of the OD stripes 202, 204 and 206 underneath the opening 304 of the SADB mask 302 are removed would be an elongate trench as viewed through the mask opening 304 in the top plan view of FIG. 3. In other embodiments, one or more openings may be provided in the SADB mask and aligned with one or more gates designated as tie-off gates to be removed, and each opening of the SADB mask need not be rectangular in shape as long as it is aligned with one or more tie-off gates selected for removal.

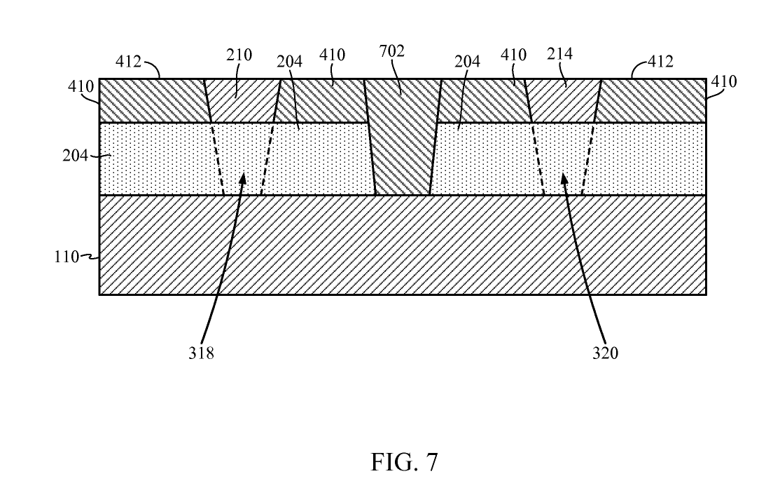

FIG. 7 is a sectional view of the FinFET device of FIG. 6 after the void 602 created by the removal of the tie-off gate and the portion of the OD stripe underneath the tie-off gate is filled with an insulating dielectric 702. In an embodiment, the polysilicon gate region 402 of the tie-off gate 310 and the portion 404 of the OD stripe 204 underneath the polysilicon gate region 402 of the tie-off gate 310 as shown in FIG. 4 are completely removed to provide good electrical isolation between transistors 318 and 320 adjacent to the insulating dielectric 702, that is, to prevent leakage currents between the transistors 318 and 320.

In an embodiment, the SADB mask 302 may be removed before the insulating dielectric 702 fills the void 602 created by the removal of the tie-off gate 310 and the portion of the OD stripe underneath it. In an embodiment, the insulating dielectric 702 may be filled to slightly above the level of the top surface 412 of the oxide layer 410. In a further embodiment, after the insulating dielectric 702 fills the void 602, a gentle chemical mechanical planarization (CMP) process may be performed to smooth the top surface 412 of the oxide layer 410 and the insulating dielectric 702 which has filled the void created by the removal of the tie-off gate. In yet a further embodiment, a metal gate process may be performed in a conventional manner to provide gate electrodes by replacing the polysilicon gates of transistors with metal, serving as circuit elements in the integrated circuit device, that is, transistors not removed by the SADB masking and removal processes described above.

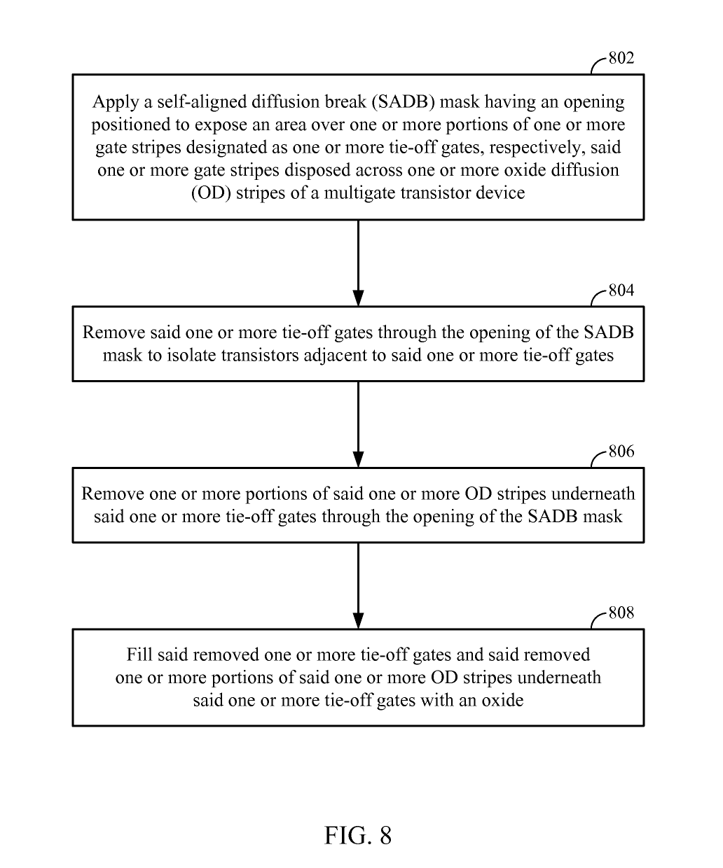

FIG. 8 is flowchart illustrating an embodiment of a method for fabricating an integrated circuit device. In FIG. 8, a self-aligned diffusion break (SADB) mask is placed over a multigate transistor device, such as a FinFET device, as shown in step 802. In an embodiment, the SADB mask has an opening to expose an area over one or more portions of one or more gate stripes designated as one or more tie-off gates, respectively. In an embodiment, the gate stripes are disposed across one or more oxide diffusion (OD) stripes of the multigate transistor device. In step 804, the tie-off gates are removed through the opening of the SADB mask to isolate transistors adjacent to the tie-off gates. In step 806, one or more portions of one or more OD stripes underneath one or more tie-off gates designated for removal are also removed through the opening of the SADB mask to create a void. In step 808, the void created by removing the tie-off gates and portions of OD stripes underneath the tie-off gates is filled with an oxide to provide electrical isolation, that is, to prevent leakage current flow between transistors adjacent to the oxide fill in place of the removed tie-off gates in the integrated circuit device. In a further embodiment, as described above with respect to FIG. 7, the top surface of the oxide fill may be made substantially even with the top surface of the gate stripes by a gentle chemical mechanical planarization (CMP) process. In yet a further embodiment, a gate metal process may be performed to provide metal gate electrodes to replace the polysilicon gates of transistors not removed by the SADB masking and removal process.

While the foregoing disclosure describes illustrative embodiments, it should be noted that various changes and modifications could be made herein without departing from the scope of the appended claims. The functions, steps or actions in the method and apparatus claims in accordance with the embodiments described herein need not be performed in any particular order unless explicitly stated otherwise. Furthermore, although elements may be described or claimed in the singular, the plural is contemplated unless limitation to the singular is explicitly stated.

1. A method of making an integrated circuit, comprising:
applying a self-aligned diffusion break (SADB) mask to a multigate transistor device comprising a plurality of transistors, the SADB mask having an opening positioned to expose an area over at least one portion of at least one gate stripe designated as at least one tie-off gate, said at least one gate stripe disposed across at least one oxide diffusion (OD) stripe of the multigate transistor device; and
removing said at least one tie-off gate through the opening of the SADB mask to isolate transistors adjacent to said at least one tie-off gate.

2. The method of claim 1, wherein the transistors comprise a plurality of multigate field effect transistors (FETs).

3. The method of claim 2, wherein the multigate FETs comprise a plurality of fin-shaped field effect transistors (FinFETs).

4. The method of claim 1, wherein said at least one OD stripe comprises at least one continuous OD stripe before the step of removing said at least one tie-off gate.

5. The method of claim 1, further comprising a plurality of OD stripes substantially in parallel to one another.

6. The method of claim 1, further comprising a plurality of gate stripes substantially in parallel to one another.

7. The method of claim 1, wherein said at least one gate stripe is substantially perpendicular to said at least one OD stripe.

8. The method of claim 1, wherein the step of removing said at least one tie-off gate comprises etching said at least one tie-off gate through the opening of the SADB mask.

9. The method of claim 1, further comprising removing at least one portion of said at least one OD stripe underneath said at least one tie-off gate through the opening of the SADB mask.

10. The method of claim 9, further comprising filling said removed at least one tie-off gate and said removed at least one portion of said at least one OD stripe underneath said at least one tie-off gate with an insulating dielectric.

11. A method for making an integrated circuit, comprising the steps for:
applying a self-aligned diffusion break (SADB) mask to a multigate transistor device comprising a plurality of transistors, the SADB mask having an opening positioned to expose an area over at least one portion of at least one gate stripe designated as at least one tie-off gate, said at least one gate stripe disposed across at least one oxide diffusion (OD) stripe of the multigate transistor device; and
removing said at least one tie-off gate through the opening of the SADB mask to isolate transistors adjacent to said at least one tie-off gate.

12. The method of claim 11, wherein the transistors comprise a plurality of multigate field effect transistors (FETs).

13. The method of claim 12, wherein the multigate FETs comprise a plurality of fin-shaped field effect transistors (FinFETs).

14. The method of claim 11, wherein said at least one OD stripe comprises at least one continuous OD stripe before the step of removing said at least one tie-off gate.

15. The method of claim 11, further comprising a plurality of OD stripes substantially in parallel to one another.

16. The method of claim 11, further comprising a plurality of gate stripes substantially in parallel to one another.

17. The method of claim 11, wherein said at least one gate stripe is substantially perpendicular to said at least one OD stripe.

18. The method of claim 11, wherein the step for removing said at least one tie-off gate comprises the step for etching said at least one tie-off gate through the opening of the SADB mask.

19. The method of claim 11, further comprising the step for removing at least one portion of said at least one OD stripe underneath said at least one tie-off gate through the opening of the SADB mask.

20. The method of claim 19, further comprising the step for filling said removed at least one tie-off gate and said removed at least one portion of said at least one OD stripe underneath said at least one tie-off gate with an insulating dielectric.

21. An integrated circuit device, comprising:
a plurality of gate stripes;
a plurality of oxide diffusion (OD) stripes disposed across and in electrical contact with the plurality of gate stripes, wherein at least one portion of at least one of the plurality of gate stripes and at least one portion of at least one of the plurality of OD stripes are removed to form at least one void; and
an insulating dielectric in said at least one void to isolate transistors adjacent to said at least one void.

22. The integrated circuit device of claim 21, wherein the plurality of gate stripes are substantially parallel to one another, and wherein the plurality of OD stripes are substantially parallel to one another.

23. The integrated circuit device of claim 21, wherein the plurality of OD stripes are substantially perpendicular to the plurality of gate stripes.

24. The integrated circuit device of claim 21, wherein the integrated circuit device comprises a plurality of field effect transistors (FETs).

25. The integrated circuit device of claim 24, wherein the plurality of FETs comprise a plurality of fin-shaped field effect transistors (FinFETs).

26. The integrated circuit device of claim 21, wherein the integrated circuit device is a multigate transistor device.

27-30. (canceled)
